(19) United States
(12) Patent Application Publication
(10) Pub. No.: US 2017/0125873 A1
(43) Pub. Date: May 4, 2017

(54) SYSTEMS AND METHODS FOR CASCADING QUADRATURE COUPLERS FOR FLAT FREQUENCY RESPONSE

(71) Applicant: Honeywell International Inc., Morris Plains, NJ (US)

(72) Inventor: Adam M. Kroening, Atlanta, GA (US)

(21) Appl. No.: 14/930,386

(22) Filed: Nov. 2, 2015

(51) Int. Cl. H01P 5/22; H01P 11/00; H01P 5/12; H03H 2/00

(52) U.S. Cl. CPC H01P 5/12; H03H 2/006; H03H 2/008; H01P 11/00

(57) ABSTRACT

Systems and methods for cascading quadrature couplers for flat frequency response are provided. In certain embodiments, a system for dividing/combining power comprises one or more 1:N couplers, wherein the one or more 1:N couplers couple power between an input and N different outputs, wherein one or more sets of two outputs in the N different outputs provide signals having different amplitudes; and one or more 2:2 quadrature couplers having inputs that are respectively connected to a subset of the one or more sets of two outputs.

### BACKGROUND

Power combiners and/or dividers are commonly used components in systems such as beam forming networks. For example, a 1:M power divider network can be used to distribute the power from a transmitter to the M elements of a phased array antenna. In the reverse direction, the same network can act as an M:1 power combiner network to combine the received energy from the M elements of a phased array antenna to a single receiver. These power divider/combiner networks may provide an equal power distribution or a tapered power distribution.

Frequently, these networks are constructed from a cascade of 1:N couplers, where N is typically 2. In certain implementations, these 1:2 couplers may be 4 port devices with one port terminated in a load. The couplers may be quadrature (90° couplers), where the insertion phase of one output port lags the other by 90°. However, in certain implementations, where there are multiple couplers, a system may be subject to particular limitations. For example, there may be significant amplitude variation between output paths in the 1:2 power dividers (input paths when combining). In certain systems, three of these 1:2 power dividers may be cascaded to form a 1:4 power divider, which cascading may double the amplitude variation.

### SUMMARY

Systems and methods for cascading quadrature couplers for flat frequency response are provided. In certain embodiments, a system for dividing/combining power comprises one or more 1:N couplers, wherein the one or more 1:N couplers couple power between an input and N different outputs, wherein one or more sets of two outputs in the N different outputs provide signals having different amplitudes; and one or more 2:2 quadrature couplers having inputs that are respectively connected to a subset of the one or more sets of two outputs.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1A is a schematic of a power divider in one embodiment described in the present disclosure;

FIG. 1B is a graph of a frequency response for a power divider in one embodiment described in the present disclosure;

FIG. 2A is a schematic of a power divider in one embodiment described in the present disclosure;

FIG. 2B is a graph of a frequency response for a power divider in one embodiment described in the present disclosure;

FIG. 3A is a schematic of a power divider in one embodiment described in the present disclosure;

FIG. 3B is a graph of a frequency response for a power divider in one embodiment described in the present disclosure;

FIG. 4 is a schematic for a power divider in one embodiment described in the present disclosure; and

FIG. 5 is a flow diagram for a method for fabricating a power divider in one embodiment described in the present disclosure.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual steps may be performed. The following detailed description is, therefore, not to be taken in a limiting sense.

Embodiments described herein provide cascading quadrature couplers for a flat frequency response. In a 1:4 power divider that is comprised of cascaded 1:2 power dividers, the four output ports each consist of a unique combination of coupled and/or through path performance. As such, the amplitude variation for the 1:4 power divider may be as much as twice the amplitude variation of the 1:2 power divider. To reduce the amplitude variation, the two output ports of the 1:4 power divider that differ by the greatest magnitude may be connected to a 2:2 power divider in such a way that the output ports of the 2:2 power divider provide signals having amplitudes that substantially correspond to the average amplitude of the signals received through the input ports. As couplers can be used to average the amplitude of signals, a series of cascaded power dividers (combiners), may be used to provide a flat frequency response.

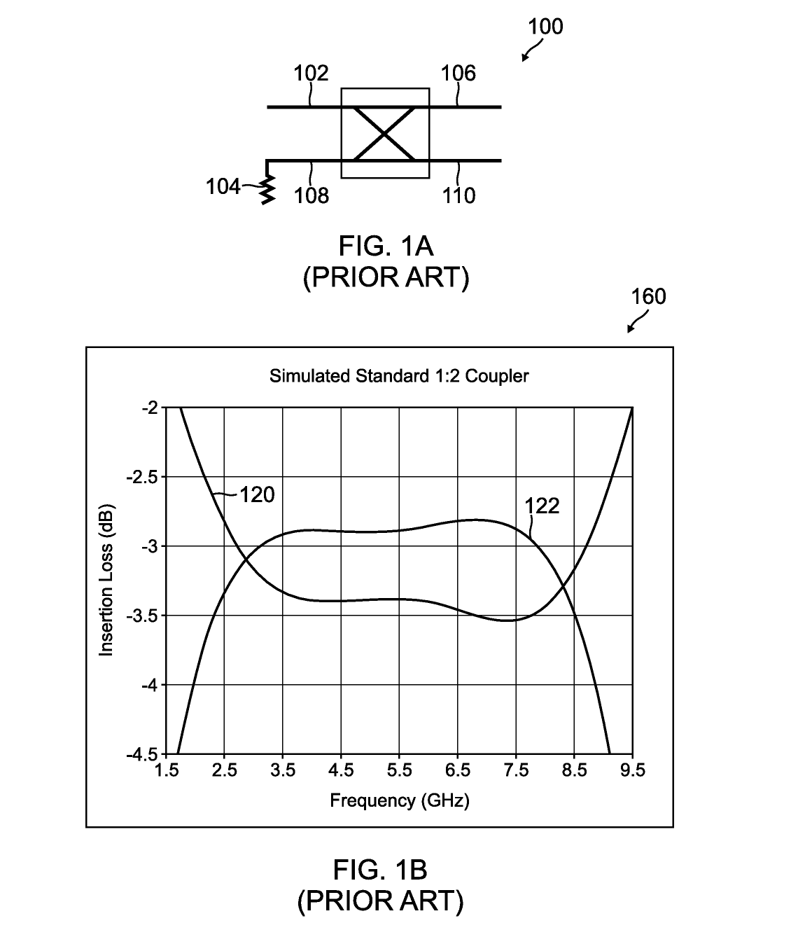

FIG. 1A illustrates a schematic of a 1:2 power divider 100 as is known to one having skill in the art. With regards to the phrase, “power divider”, as used herein, the phrase also refers to a combiner, as a power divider being used for transmission through the power divider functions as a combiner for the reception of signals through the same power dividers. Accordingly, the principles discussed herein apply to both the operation of power dividers and combiners. As stated, power divider 100 includes four ports, where one port is terminated in a load. For example, power divider 100 includes ports 102, 106, 108, and 110, where port 108 is terminated in a load 104. A signal received on port 102 will be either passed through to port 106 or coupled to port 110. The phase of the coupled signal that is provided through port 110 may lag 90° behind the phase of the signal passed through to the port 106.

FIG. 1B is a graph 160 illustrating the performance of an exemplary power divider as illustrated in FIG. 1A. In the graph, the line 120 illustrates the frequency response of the power divider for the coupled signal. The line 122 illustrates the frequency response of the power divider for the through signal. As illustrated, the frequency response is over the range 1.5 to 9.5 GHz, however other frequency ranges are also possible as understood by one having skill in the art. As shown, there is a variation in the amplitude between the through and the coupled paths. For example, there is about a 0.7 dB amplitude variation between the through and coupled paths. The coupled signal could be described as over coupled because more than half of the power is coupled to this port in the center of the frequency band. Likewise, the through signal could be described as under coupled because less than half of the power is coupled to this port in the center of the frequency band. Amplitude variations affect the performance of systems that include power dividers such as the coupler 100. For example, when the power divider is part of a system for providing a feed to a phased array antenna, the amplitude variations may degrade the beam pattern of the phased array antenna.

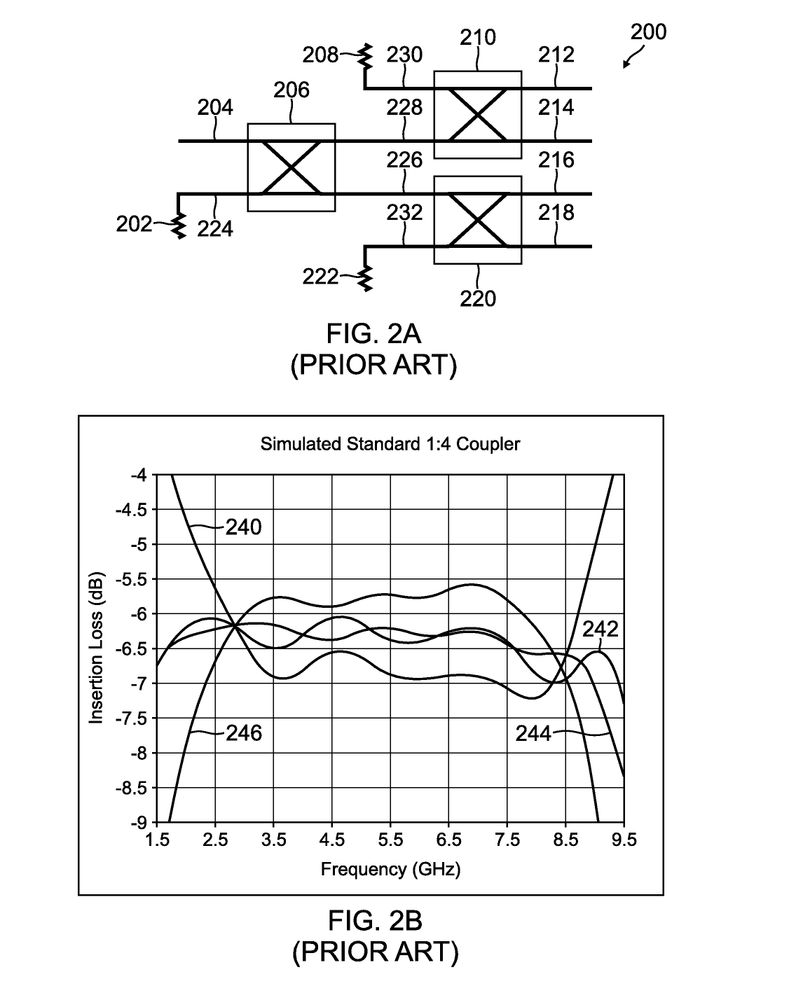

FIG. 2A is a schematic illustrating the coupling of three 1:2 dividers, such as the 1:2 power divider described above in FIG. 1A, to form a 1:4 power divider 200. The 1:4 power divider 200 includes 3 cascaded 1:2 power dividers 206, 210, and 220. For example, two of the input ports for the power dividers 210 and 220 are coupled to the output ports of the power divider 206 respectively at ports 228 and 226. The other two input ports 230 and 232 of the power dividers 210 and 220 are respectively coupled to loads 208 and 222. In a similar fashion, the input port 224 of power divider 206 is coupled to a load 202. Accordingly, the 1:4 power divider 200 has four outputs 212, 214, 216, and 218.

In certain embodiments, each output of the power divider 200 represents a different combination of a through and coupled signal. For example, the signal that is provided from output 212 is passed through power divider 206 and then coupled by power divider 210 into the output 212. The signal that is provided from output 214 is passed through power divider 206 and then passed through power divider 210 into output 214. The signal that is provided from output 216 is coupled from power divider 206 into power divider 220 and then passed through power divider 220 into output 216. The signal that is provided from output 218 is coupled from power divider 206 into power divider 220 and then coupled by power divider 220 into output 216.

As each output is a different combination of a signal being passed through and/or being coupled by multiple power dividers, each signal provided from one of the outputs 212, 214, 216, and 218 has a different frequency response that is determined by the accumulated effects of being passed through and/or coupled by multiple power dividers. FIG. 2B illustrates an exemplary frequency response for a 1:4 power divider such as the power divider 200 described above in FIG. 2A. Line 240 corresponds with the frequency response of a signal produced at output 218. Line 242 corresponds with the frequency response of a signal produced at output 216. Line 244 corresponds with the frequency response of a signal produced at output 212. Line 246 corresponds with the frequency response of a signal produced at output 214. As shown the amplitude variation for the frequency response is twice that of the 1:2 power divider described in FIG. 1. For example, the amplitude of the frequency response associated with output 218, illustrated by line 240, differs substantially from the amplitude of the frequency response associated with output 214, illustrated by line 246. The difference arises because the signal produced from output 218 is coupled by both power dividers 206 and 220, where the signal produced from output 214 is passed through both power dividers 206 and 210. In contrast, the amplitude of the frequency response associated with the outputs 212 and 216, illustrated respectively by lines 242 and 244, have less variation because the signals produced from outputs 212 and 216 are both coupled through a power divider and passed through a power divider. The relative phase of the four outputs follows a similar pattern, wherein the signal from output 218 lags the phase of the signal from output 212 by 180°, and the signals from output 214 and output 216 lag the phase of the signal from output 212 by 90°.

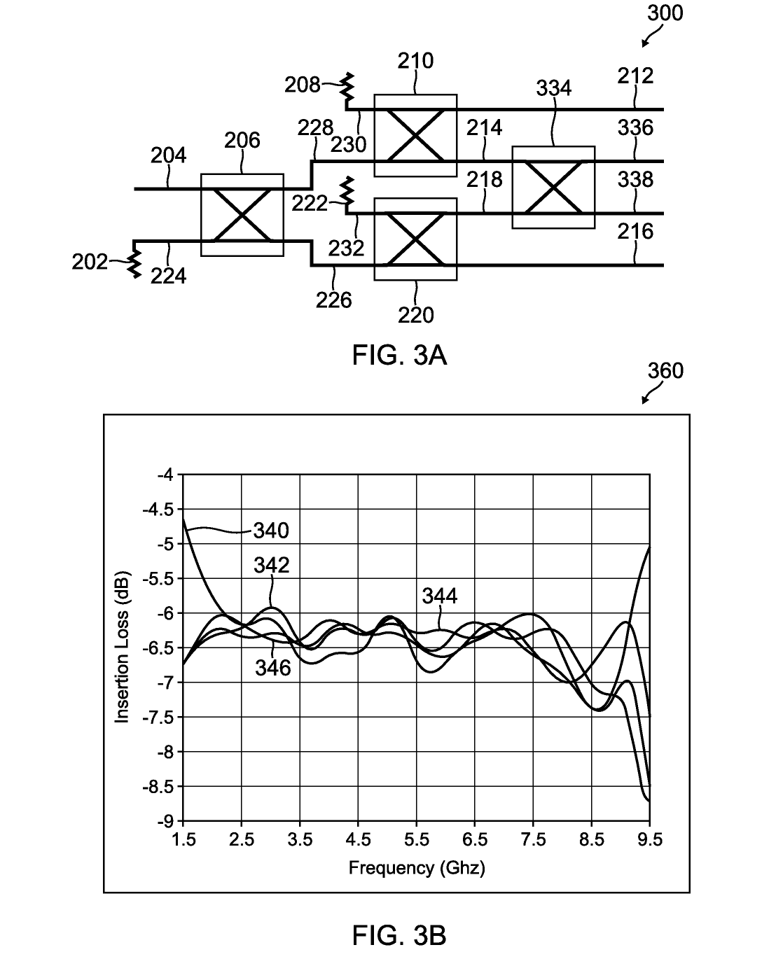

FIG. 3A illustrates a 1:4 power divider 300 that has a flatter frequency response for the signals produced from the four outputs. As illustrated, numbered items that have similar numbered items in power divider 200 and power divider 300 function substantially similar to one other. To provide the desired frequency response by reducing amplitude variation, the outputs 214 and 218, as described above are connected to a 2:2 power divider 334. Because the outputs of 214 and 218 are 180° out of phase with one another, the 2:2 power divider combines half of the power from 214 and half of the power from 218 into output 338. Also, the 2:2 power divider combines half of the power from 214 and half of the power from 218 into output 336. By connecting the outputs 214 and 218 into the 2:2 power divider, the signals provided by 336 and 338 represent the average of the signals provided from outputs 214 and 218. By connecting the 2:2 quadrature coupler as described above to outputs 214 and 218, the four output ports 212, 216, 336, and 338 may have substantially the same amplitude contributions from through and coupled paths. FIG. 3B illustrates a graph 360 illustrating the frequency response of the signals produced from the output ports 212, 216, 336, and 338. As shown, the amplitude variation is significantly reduced between 2.5 and 8.5 GHz, such that the variation in insertion loss is generally less than 0.5 dB. As such, by connecting the 2:2 power divider to ports 214 and 218 of a standard 1:4 power divider described in FIG. 2, the amplitude variation is significantly reduced. Thus, a phased antenna array driven by the 1:4 power divider 300 may exhibit improved performance.

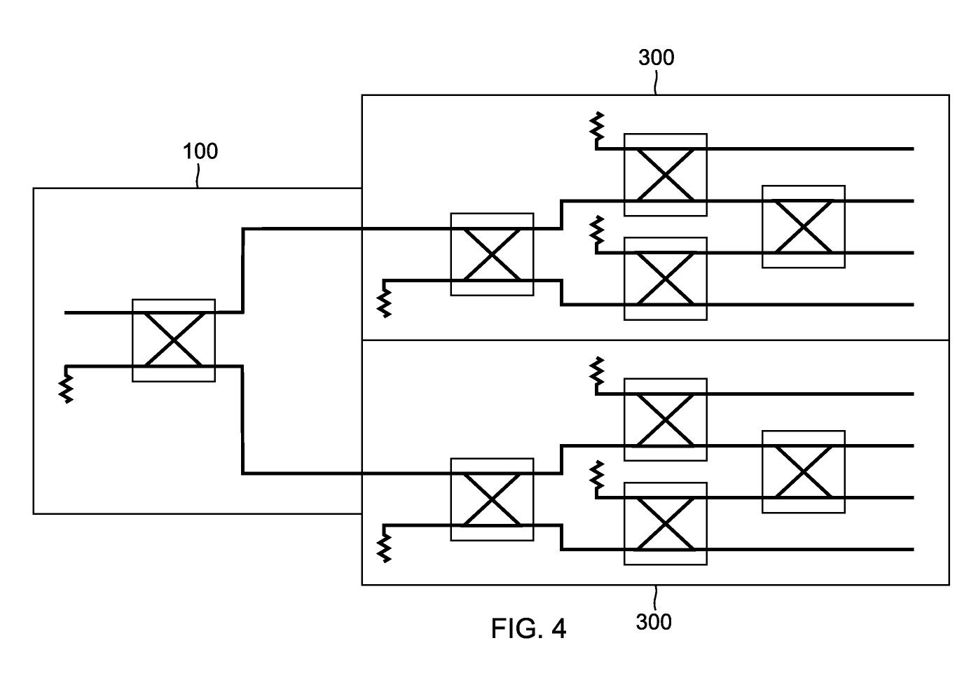

As disclosed above, the addition of a 2:2 power divider to the over (through) and under (coupled) coupled ports of a 1:4 power divider may be extended to a broader range of power dividers beyond the 1:4 power divider. For example, FIG. 4 illustrates one exemplary implementation of a 1:8 power divider. To form the 1:8 power divider, the 1:4 power dividers 300 disclosed in FIG. 3 may be coupled to the outputs of a 1:2 power divider 100 as disclosed in FIG. 1. As shown, the 2:2 couplers may be used to average divergent outputs from cascaded power dividers in order to provide a more desirable frequency response. As one having skill in the art could appreciate, multiple 2:2 couplers can be used in a 1:N power divider to average out multiple sets of outputs with either a 0° or 180° relative phase relationship such that the amplitude variation in the multiple output is substantially similar. In another implementation, the 2:2 coupler may be connected to a single 1:2 power divider with a 90° phase shift segment added to one of the outputs such that the outputs from the single 1:2 power divider are averaged. The 90° degree phase shift element could be added to either output, as the phase relationship of the inputs to the 2:2 coupler will be 0° if the 90° phase lag element is added only to the through path of the 1:2 power divider and the phase relationship of the inputs to the 2:2 coupler will be 180° if the 90° phase lag element is added only to the coupled path of the 1:2 power divider.

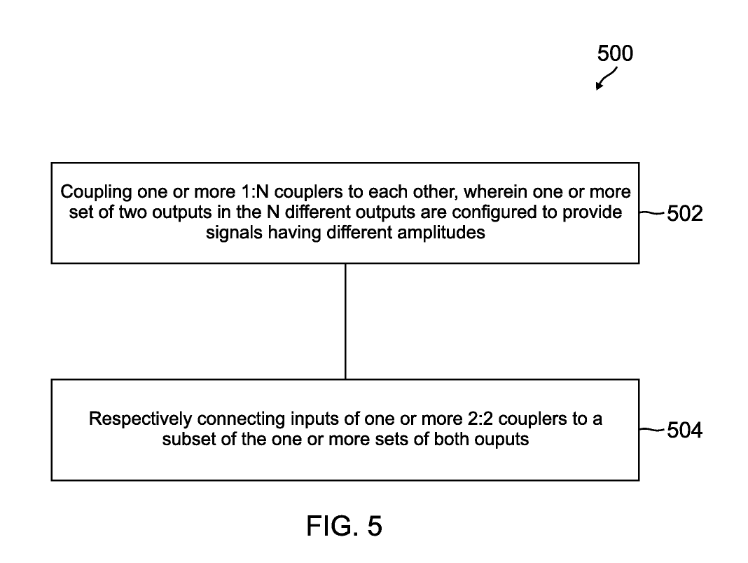

FIG. 5 is a flow diagram of a method 500 for constructing a power divider as described above in relation to FIGS. 3A and 4. To fabricate the power divider, method 500 proceeds at 502 where one or more 1:N couplers are coupled to each other, wherein one or more sets of two outputs in the N different outputs are configured to provide signals having different amplitudes. For example, a 1:4 coupler may have an over coupled output and an under coupled output. The set of two outputs may have significantly divergent amplitudes such that the variation in amplitude may affect the performance of connected systems. Method 500 then proceeds at 504 where inputs of one or more 2:2 couplers are respectively coupled to a subset of the one or more sets of two outputs. For example, the inputs of the 2:2 coupler may be connected to the over coupled and under coupled outputs of the 1:4 coupler. Accordingly, half of the power from the over coupled output and half of the power from the under coupled output will combine with each other at each output of the 2:2 coupler. As such, the 2:2 coupler may provide an output that is the average of the over-coupled and under coupled output from the 1:4 coupler.

### Example Embodiments

Example 1 includes a system for dividing/combining power, the system comprising: one or more 1:N couplers, wherein the one or more 1:N couplers couple power between an input and N different outputs, wherein one or more sets of two outputs in the N different outputs provide signals having different amplitudes; and one or more 2:2 quadrature couplers having inputs that are respectively connected to a subset of the one or more sets of two outputs.

Example 2 includes the system of Example 1, wherein the subset of the one or more sets of two outputs comprise the sets of two outputs wherein the difference between the amplitude of the signals provided by the outputs in the set of two outputs exceeds a threshold value for amplitude variation.

Example 3 includes the system of any of Examples 1-2, wherein the outputs for the one or more 2:2 quadrature couplers and the outputs of the one or more 1:N couplers that are not connected to one of the one or more 2:2 quadrature couplers and other 1:N couplers in the one or more 1:N couplers are provided as outputs from the power divider.

Example 4 includes the system of any of Examples 1-3, wherein the one or more 1:N couplers are comprised of one or more 2:2 quadrature couplers having an input terminated in a load.

Example 5 includes the system of any of Examples 1-4, wherein the inputs to a 2:2 coupler in the one or more 2:2 couplers have a relative phase of 180° in relation to one another.

Example 6 includes the system of any of Examples 1-5, wherein a set of two outputs in the one or more sets of two outputs has one output that is under coupled through the one or more 1:N couplers and one output that is over coupled through the one or more 1:N couplers.

Example 7 includes the system of any of Examples 1-6, wherein the one or more 1:N couplers comprises three cascaded 1:2 couplers forming a 1:4 coupler, the 1:4 coupler comprising a first 1:2 coupler, wherein the first 1:2 coupler has a first through output and a first coupled output; a second 1:2 coupler, wherein the input of the second 1:2 coupler is connected to the first through output of the first 1:2 coupler, the second 1:2 coupler having a second through output and a second coupled output; a third 1:2 coupler, wherein the input of the third 1:2 coupler is connected to the first coupled output of the first 1:2 coupler; the third 1:2 coupler having a third through output and a third coupled output; and wherein a first input of a 2:2 coupler in the one or more 2:2 couplers is connected to the second through output and a second input of the 2:2 coupler is connected to the third coupled output.

Example 8 includes the system of Example 7, wherein the 1:4 coupler forms a module that is coupled to other 1:N couplers in the one or more 1:N couplers.

Example 9 includes a method for fabricating a power divider/combiner, the method comprising: coupling one or more 1:N couplers to each other, wherein the one or more 1:N couplers are configured to couple power between an input and N different outputs, wherein one or more sets of two outputs in the N different outputs are configured to provide signals having different amplitudes; and respectively connecting inputs of one or more 2:2 couplers to a subset of the one or more sets of two outputs.

Example 10 includes the method of Example 9, wherein the subset of the one or more sets of two outputs comprise the sets of two outputs wherein the difference between the amplitude of the signals provided by the outputs in the set of two outputs exceeds a threshold value for amplitude variation.

Example 11 includes the method of any of Examples 9-10, further comprising providing the outputs for the one or more 2:2 quadrature couplers and the outputs of the one or more 1:N couplers that are not connected to one of the one or more 2:2 quadrature couplers and other 1:N couplers in the one or more 1:N couplers as outputs for a power divider.

Example 12 includes the method of Example 11, wherein the outputs for the power divider drive a phased antenna array.

Example 13 includes the method of any of Examples 9-12, wherein the one or more 1:N couplers are comprised of one or more 2:2 quadrature couplers having an input terminated in a load.

Example 14 includes the method of any of Examples 9-13, wherein a set of two outputs in the one or more sets of two outputs has one output that is under coupled through the one or more 1:N couplers and one output that is over coupled through the one or more 1:N couplers.

Example 15 includes the method of any of Examples 9-14, wherein the one or more 1:N couplers comprises three cascaded 1:2 couplers forming a 1:4 coupler, the 1:4 coupler comprising a first 1:2 coupler, wherein the first 1:2 coupler has a first through output and a first coupled output; a second 1:2 coupler, wherein the input of the second 1:2 coupler is connected to the first through output of the first 1:2 coupler, the second 1:2 coupler having a second through output and a second coupled output; a third 1:2 coupler, wherein the input of the third 1:2 coupler is connected to the first coupled output of the first 1:2 coupler; the third 1:2 coupler having a third through output and a third coupled output; and wherein a first input of a 2:2 coupler in the one or more 2:2 couplers is connected to the second through output and a second input of the 2:2 coupler is connected to the third coupled output.

Example 16 includes the method of Example 15, wherein the 1:4 coupler forms a module that is coupled to other 1:N couplers in the one or more 1:N couplers.

Example 17 includes a system for a coupler, the coupler comprising a first 1:2 coupler, wherein the first 1:2 coupler has a first through output and a first coupled output; a second 1:2 coupler, wherein the input of the second 1:2 coupler is connected to the first through output of the first 1:2 coupler, the second 1:2 coupler having a second through output and a second coupled output; a third 1:2 coupler, wherein the input of the third 1:2 coupler is connected to the first coupled output of the first 1:2 coupler; the third 1:2 coupler having a third through output and a third coupled output; and wherein a first input of a 2:2 coupler in the one or more 2:2 couplers is connected to the second through output and a second input of the 2:2 coupler is connected to the third coupled output.

Example 18 includes the system of Example 17, wherein the coupler forms a coupler module, wherein a first module input for a first coupler module is connected to a first output of a fourth 1:2 coupler and a second module input for a second coupler module is connected to a second output of the fourth 1:2 coupler.

Example 19 includes the system of any of Examples 17-18, wherein the second coupled output, the third through output, and outputs of the 2:2 coupler drive a phased antenna array.

Example 20 includes the system of any of Examples 17-19, wherein the first 1:2 coupler, the second 1:2 coupler, and the third 1:2 coupler are 2:2 quadrature couplers having an input terminated in a load.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A system for dividing/combining power, the system comprising:
one or more 1:N couplers, wherein the one or more 1:N couplers couple power between an input and N different outputs, wherein one or more sets of two outputs in the N different outputs provide signals having different amplitudes; and
one or more 2:2 quadrature couplers having inputs that are respectively connected to a subset of the one or more sets of two outputs.

2. The system of claim 1, wherein the subset of the one or more sets of two outputs comprise the sets of two outputs wherein the difference between the amplitude of the signals provided by the outputs in the set of two outputs exceeds a threshold value for amplitude variation.

3. The system of claim 1, wherein the outputs for the one or more 2:2 quadrature couplers and the outputs of the one or more 1:N couplers that are not connected to one of the one or more 2:2 quadrature couplers and other 1:N couplers in the one or more 1:N couplers are provided as outputs from the power divider.

4. The system of claim 1, wherein the one or more 1:N couplers are comprised of one or more 2:2 quadrature couplers having an input terminated in a load.

5. The system of claim 1, wherein the inputs to a 2:2 coupler in the one or more 2:2 couplers have a relative phase of 180° in relation to one another.

6. The system of claim 1, wherein a set of two outputs in the one or more sets of two outputs has one output that is under coupled through the one or more 1:N couplers and one output that is over coupled through the one or more 1:N couplers.

7. The system of claim 1, wherein the one or more 1:N couplers comprises three cascaded 1:2 couplers forming a 1:4 coupler, the 1:4 coupler comprising
a first 1:2 coupler, wherein the first 1:2 coupler has a first through output and a first coupled output;
a second 1:2 coupler, wherein the input of the second 1:2 coupler is connected to the first through output of the first 1:2 coupler, the second 1:2 coupler having a second through output and a second coupled output;
a third 1:2 coupler, wherein the input of the third 1:2 coupler is connected to the first coupled output of the first 1:2 coupler; the third 1:2 coupler having a third through output and a third coupled output; and
wherein a first input of a 2:2 coupler in the one or more 2:2 couplers is connected to the second through output and a second input of the 2:2 coupler is connected to the third coupled output.

8. The system of claim 7, wherein the 1:4 coupler forms a module that is coupled to other 1:N couplers in the one or more 1:N couplers.

9. A method for fabricating a power divider/combiner, the method comprising:
coupling one or more 1:N couplers to each other, wherein the one or more 1:N couplers are configured to couple power between an input and N different outputs, wherein one or more sets of two outputs in the N different outputs are configured to provide signals having different amplitudes; and
respectively connecting inputs of one or more 2:2 couplers to a subset of the one or more sets of two outputs.

10. The method of claim 9, wherein the subset of the one or more sets of two outputs comprise the sets of two outputs wherein the difference between the amplitude of the signals provided by the outputs in the set of two outputs exceeds a threshold value for amplitude variation.

11. The method of claim 9, further comprising providing the outputs for the one or more 2:2 quadrature couplers and the outputs of the one or more 1:N couplers that are not connected to one of the one or more 2:2 quadrature couplers and other 1:N couplers in the one or more 1:N couplers as outputs for a power divider.

12. The method of claim 11, wherein the outputs for the power divider drive a phased antenna array.

13. The method of claim 9, wherein the one or more 1:N couplers are comprised of one or more 2:2 quadrature couplers having an input terminated in a load.

14. The method of claim 9, wherein a set of two outputs in the one or more sets of two outputs has one output that is under coupled through the one or more 1:N couplers and one output that is over coupled through the one or more 1:N couplers.

15. The method of claim 9, wherein the one or more 1:N couplers comprises three cascaded 1:2 couplers forming a 1:4 coupler, the 1:4 coupler comprising
a first 1:2 coupler, wherein the first 1:2 coupler has a first through output and a first coupled output;
a second 1:2 coupler, wherein the input of the second 1:2 coupler is connected to the first through output of the first 1:2 coupler, the second 1:2 coupler having a second through output and a second coupled output;
a third 1:2 coupler, wherein the input of the third 1:2 coupler is connected to the first coupled output of the first 1:2 coupler; the third 1:2 coupler having a third through output and a third coupled output; and
wherein a first input of a 2:2 coupler in the one or more 2:2 couplers is connected to the second through output and a second input of the 2:2 coupler is connected to the third coupled output.

16. The method of claim 15, wherein the 1:4 coupler forms a module that is coupled to other 1:N couplers in the one or more 1:N couplers.

17. A system for a coupler, the coupler comprising
a first 1:2 coupler, wherein the first 1:2 coupler has a first through output and a first coupled output;
a second 1:2 coupler, wherein the input of the second 1:2 coupler is connected to the first through output of the first 1:2 coupler, the second 1:2 coupler having a second through output and a second coupled output;
a third 1:2 coupler, wherein the input of the third 1:2 coupler is connected to the first coupled output of the first 1:2 coupler; the third 1:2 coupler having a third through output and a third coupled output; and
wherein a first input of a 2:2 coupler in the one or more 2:2 couplers is connected to the second through output and a second input of the 2:2 coupler is connected to the third coupled output.

18. The system of claim 17, wherein the coupler forms a coupler module, wherein a first module input for a first coupler module is connected to a first output of a fourth 1:2 coupler and a second module input for a second coupler module is connected to a second output of the fourth 1:2 coupler.

19. The system of claim 17, wherein the second coupled output, the third through output, and outputs of the 2:2 coupler drive a phased antenna array.

20. The system of claim 17, wherein the first 1:2 coupler, the second 1:2 coupler, and the third 1:2 coupler are 2:2 quadrature couplers having an input terminated in a load.
